(19) United States
(12) Patent Application Publication
(10) Pub. No.: US 2025/0244664 A1
(43) Pub. Date: Jul. 31, 2025

(54) PHOTORESIST COMPOSITIONS AND PATTERNING METHODS

(71) Applicant: DUPONT ELECTRONIC MATERIALS INTERNATIONAL, LLC, Marlborough, MA (US)

(72) Inventor: Mitsuru HAGA, Agano-shi (JP)

(21) Appl. No.: 18/989,213

(22) Filed: Dec. 20, 2024

Related U.S. Application Data
(60) Provisional application No. 63/616,662, filed on Dec. 31, 2023.

(51) Int. Cl. G03F 7/004; C08K 5/33; C08K 5/3475; C08K 5/3492; C08K 5/45; G03F 7/36

(52) U.S. Cl. CPC G03F 7/0045; C08K 5/33; C08K 5/3475; C08K 5/34924; C08K 5/45; G03F 7/36

(57) ABSTRACT

Disclosed herein is a photoresist composition, comprising a non-ionic thioxanthone compound, a non-ionic oxime compound, or a combination of a non-ionic thioxanthone compound and a non-ionic oxime compound; a polymer comprising a first repeat unit of formula (3) and a second repeat unit of formula (4a):

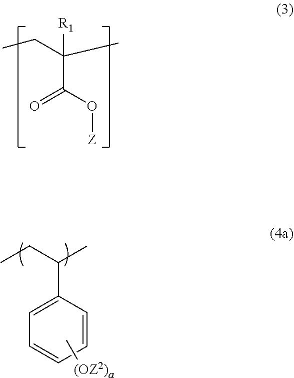

wherein in formula (3), R₁ is a hydrogen atom or a substituted or unsubstituted C₁ to C₃ alkyl group; Z is a non-hydrogen substituent comprising an acid-labile moiety; and wherein in formula (4a), a is an integer from 1 to 5 and where Z² is a hydrogen atom or a substituted or unsubstituted C₁ to C₅ alkyl group; a base quencher; a photoacid generator; and a solvent.

### CROSS-REFERENCE TO RELATED APPLICATION

This application is a nonprovisional of U.S. Provisional Application No. 63/616,662, filed on Dec. 31, 2023, the content of which is incorporated by reference herein in its entirety.

### BACKGROUND

This disclosure relates to a photoresist composition and methods of manufacture thereof. This disclosure also relates to a patterning process for manufacturing semiconductors that prevents the development of a footing profile in a photoresist pattern.

Mobile devices, devices that are part of the internet of things (IoT) and wearable electronics have over the years become smaller, lighter and thinner devices that despite increasing miniaturization use larger amounts of memory and perform increasingly larger amounts of computation.

The manufacture and packaging of these electronic devices serves an important role in the size reduction. For example, flip-chip packaging methods have been used to increase the density of I/O (Input/Output) connections between devices, especially for micro-processing unit (MPU) and dynamic random-access memory (DRAM) semiconductor chips.

Dry plasma etching is widely used in semiconductor fabrication. The manufacturing of 3D-NAND devices requires the use of a thick film photoresist that has durable etching resistance. 3D-NAND (three-dimensional NAND) is a type of flash memory technology used in data storage devices, such as solid-state drives (SSDs) and USB flash drives. The “3D” in 3D NAND refers to the stacking of memory cells in multiple layers, creating a vertical structure.

In meeting the technical specification for a thick film photoresist, there is an inclination towards increased pattern height and decreased width. To address these technical specifications, chemical amplification photoresists (CAR) are employed.

One concern in plasma etching processes that involve a chemically amplified photoresist (CAR) is the presence of ultraviolet (UV) emission, which activates the photoacid generator (PAG) present in the photoresist composition. The acid generated by the activation of the photoacid generator decomposes acid-labile groups in the polymer, accumulating and aggregating within the interior of the photoresist film. Upon surpassing a critical point, these aggregates can lead to blistering or burst out. Even when the degree of outgassing is low, it may manifest as voids when examined using a scanning microscopy inspection.

One potential solution to mitigate the outgassing issue is to reduce the amount of acid-labile components present in the photoresist composition. However, this adjustment negatively impacts the dissolution rate, proving less favorable for thick film applications. Another method of mitigating the issue is to increase the quencher base loading in the photoresist composition. Higher quencher loading has proved effective in reducing the severity of blistering. However, this reduction comes at the cost of sacrificing sensitivity.

It is therefore desirable to improve dry etching resistance by maintaining sensitivity while at the same time reducing void formation and/or blistering that is caused by UV emission during plasma etching.

### SUMMARY

Disclosed herein is a photoresist composition, comprising a non-ionic thioxanthone compound, a non-ionic oxime compound, or a combination of a non-ionic thioxanthone compound and a non-ionic oxime compound; a polymer comprising a first repeat unit of formula (3) and a second repeat unit of formula (4a):

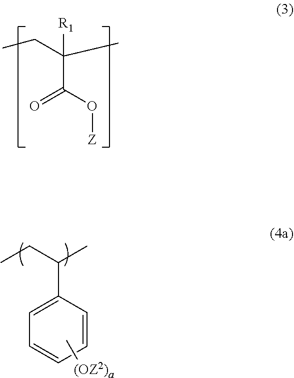

wherein in formula (3), R₁ is a hydrogen atom or a substituted or unsubstituted C₁ to C₃ alkyl group; Z is a non-hydrogen substituent comprising an acid-labile moiety; and wherein in formula (4a), a is an integer from 1 to 5 and where Z² is a hydrogen atom or a substituted or unsubstituted C₁ to C₅ alkyl group; a base quencher; a photoacid generator; and a solvent.

### BRIEF DESCRIPTION OF THE FIGURES

FIG. 1A depicts an exemplary embodiment of the substrate upon which at first layer is disposed;

FIG. 1B depicts an exemplary embodiment of the deposition of the photoresist layer on the first layer and the photopatterning of the photoresist layer and the first layer;

FIG. 1C depicts an exemplary embodiment of the development of the photoresist layer;

FIG. 1D depicts the etching of the first layer by plasma dry etching;

FIG. 2 graphically depicts the thioxanthone loading effect on unexposed area film thickness loss (UFTL) (bottom graphs), energy to −100 nm bias to nominal mask size (middle graphs) and process window at −100 nm mask bias from 1200 nm nominal (top graphs);

FIG. 3A depicts the Bossung curve of the photoresist composition without ITX (photoresist composition CF-7 from Table 1);

FIG. 3B depicts the Bossung curve for a photoresist composition with ITX (photoresist composition EX-5 from Table 1);

FIG. 4A illustrates the focus exposure matrix process window (PW) for comparative example CF-7 (which does not contain ITX) aimed at achieving a 1.1 μm space width, utilizing a 1.2 μm nominal mask;

FIG. 4B illustrates the focus exposure matrix process window (PW) for example EX-5 (which contains ITX) aimed at achieving the same space width, utilizing the same nominal mask as in FIG. 4A;

FIG. 5 depicts a series of graph that depicts the influence of non-ionic oxime compounds on the unexposed area film thickness loss (UFTL) (bottom plot), sensitivity (middle plot), and process window (top plot) for photoresist compositions that contain non-ionic oxime additives;

FIG. 6 contains Table 6, which depicts scanning electron photomicrographs of cross-sectional images of the different wafers after plasma etching.

### DETAILED DESCRIPTION

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise.

As used herein, an “acid-labile group” refers to a group in which a bond is cleaved by the catalytic action of an acid, optionally and typically with thermal treatment, resulting in a polar group, such as a carboxylic acid or an alcohol group, being formed on the polymer, and optionally and typically with a moiety connected to the cleaved bond becoming disconnected from the polymer. Such acid is typically a photo-generated acid with bond cleavage occurring during post-exposure baking. Suitable acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

In lithography, the term “under-dose area” refers to a region in the exposure conditions where the amount of light or radiation used to expose the photoresist is intentionally reduced below the standard or optimal dosage. This is a controlled variation from the nominal exposure conditions. The exposure dose in lithography is useful for defining the desired pattern on the photoresist. Under-dosing involves intentionally reducing the exposure energy during the lithographic process. This approach is sometimes used to explore the sensitivity limits of a photoresist or to deliberately induce variations in the pattern dimensions.

The term “process window” refers to the range of process conditions (such as exposure dose, focus, and depth of focus) within which the fabrication process is robust, and the desired patterns on the photoresist are formed consistently and accurately. An “improved process window” signifies an expansion or enhancement of this range, leading to more forgiving and reliable manufacturing conditions.

The term “thioxanthone” includes a non-ionic sulfur-containing heterocyclic compound that contains a thioether group (S atom) in its structure. It includes non-ionic derivatives of thioxanthones.

The term “oxime” includes non-ionic oximes and derivatives thereof. It includes non-ionic oxime esters, oxime ethers and derivatives thereof.

Disclosed herein is a photoresist composition that can be used for plasma dry etching. The photoresist composition reduces the presence of voids and other forms of photoresist damage and displays an improved process window. The photoresist composition comprises a polymer that comprises an acid-labile group, a non-ionic thioxanthone compound and/or a non-ionic oxime compound that improves the process window over a photoresist composition that contains all the same ingredients except for the non-ionic thioxanthone compound and/or a non-ionic oxime compound, a photoacid generator and a base quencher. The non-ionic thioxanthone compound and/or a non-ionic oxime compound enable the photoresist composition to have an improved process window at exposure wavelengths of 300 to 400 nanometers.

Without being limited to theory, it is believed that the non-ionic thioxanthone compound absorbs some of the UV radiation that the photoresist composition is exposed to during the plasma etching process. The absorption of UV radiation reduces acid generation from the photoacid generator, thus improving the processing window. The non-ionic oxime compounds generate a base quencher upon being exposed to UV radiation, which effectively quenches acid generated during the etching process. The quenching of acid facilitates improving the process window. It also improves the resistance against dry plasma etching.

The aforementioned photoresist composition is disposed on a substrate to form a photoresist layer. The photoresist layer is patternwise exposed to activating radiation. The exposed photoresist layer is then developed with a basic developer, thereby removing portions of the photoresist layer to form a relief pattern. The relief pattern is used as a mask during dry plasma etching.

As noted above, in a plasma etching process, the acid generated by the activation of the photoacid generator decomposes acid-labile groups in the polymer. The excess acid can aggregate within the interior of the photoresist film eventually blistering (producing voids) or bursting out of the film. The non-ionic thioxanthone compound and/or the non-ionic oxime compound enable the photoresist composition to display improved etching resistance by reducing the number of such voids. These compounds absorb UV emission and reduce PAG decomposition during plasma etching that affect void formation by preventing cleavage of acid labile polymer.

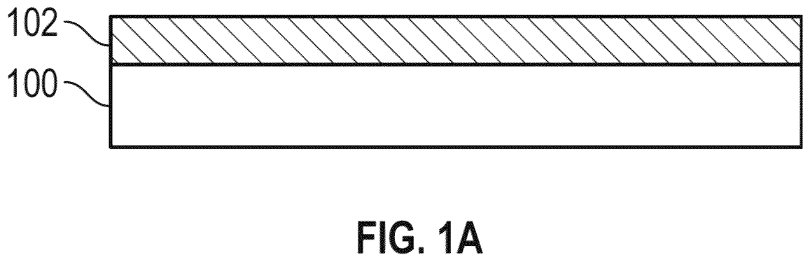

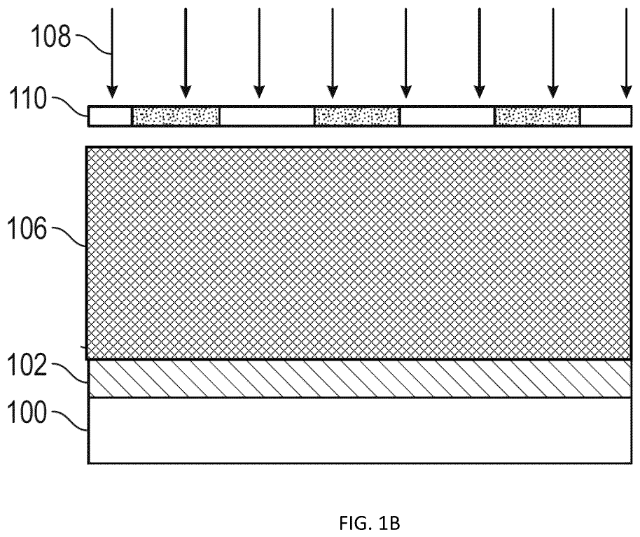

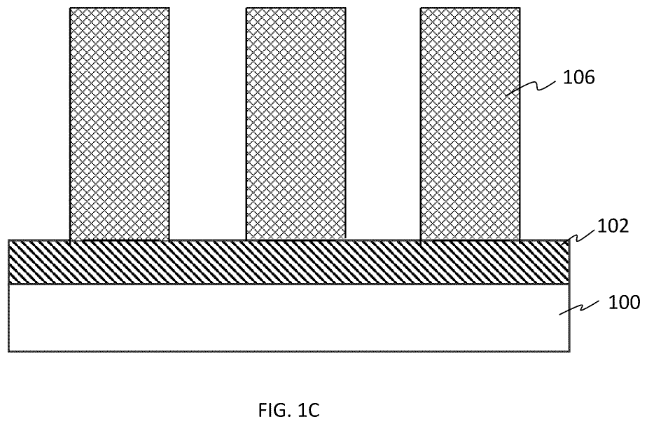

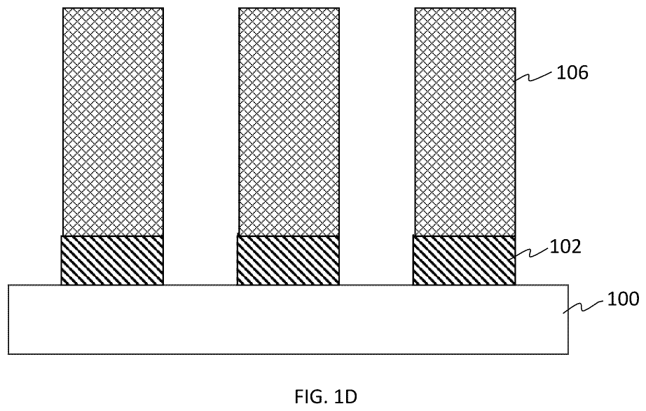

FIGS. 1A-1D depict a method of forming a pattern on a substrate using dry etching. FIG. 1A depicts the substrate 100 upon which a first layer 102 is disposed. FIG. 1B depicts the coating of the photoresist layer 106 on the first layer 102 followed by photo-exposure of the photoresist layer 106. The photoresist layer 106 comprises a photoacid generator and a polymer that contains an acid labile group. After coating the photoresist layer 106, the photoresist layer 106 is patternwise exposed to activating radiation 108 through a photomask 110 having optically opaque and optically transparent regions. A UV light having a wavelength of 10 to 400 nanometers is used for photo patterning.

FIG. 1C depicts the development of the exposed parts of the photoresist layer 106. The exposed portions of the photoresist layer 106 are removed via aqueous alkaline developer as seen in the FIG. 1C. Exposed portions of the first layer 102 and/or the substrate 100 are then removed by plasma dry etching as seen in the FIG. 1D. During the dry plasma etching, the photoresist layer 106 (with exposed portions removed) functions as an etching mask. This etching mask exposes portions of the first layer 102 and/or the substrate 100 so that they can be removed during the etching.

### The Substrate

Examples of the substrate include, but are not limited to, silicon wafers, glass substrates and plastic substrates, such substrates optionally including one or more layers or features formed thereon. A preferred substrate is a silicon wafer.

### The First Layer

FIG. 1A depicts the substrate 100 upon which at first layer 102 is disposed. The first layer 102 is selectively removed via dry plasma mask etching. The first layer comprises a metal, a ceramic, or a combination thereof. The metal comprises aluminum, copper, titanium, silicon, or combination thereof. The ceramic comprises silicon oxide, silicon nitride, titanium nitride, or a combination thereof. In an embodiment, the first layer may comprise a stack of multiple layers, where alternating layers comprise silicon oxide and silicon nitride. The stack may comprise 10 to 500 such alternating layers.

### The Photoresist Layer

FIG. 1B depicts the deposition of the photoresist layer 106 on the first layer 102 to be etched. The photoresist composition 106 comprises a polymer that comprises an acid-labile group; a photoacid generator; a quencher and a solvent. The polymer comprises first repeat units that comprise an acid labile group. In an embodiment, the polymer comprises second repeat units that comprise a vinyl aromatic group. In an embodiment, the polymer comprises a first repeat unit of formula (3) and a second repeat unit of formula (4a):

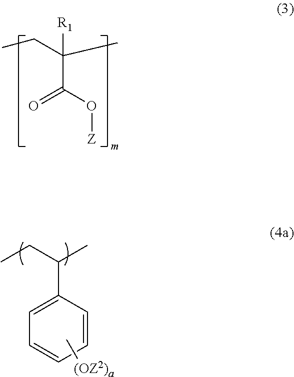

wherein in formula (3), R₁ is a hydrogen atom or substituted or unsubstituted C₁-C₃ alkyl; Z is a non-hydrogen substituent comprising an acid-labile moiety; and wherein in formula (4a), “a” is an integer that includes 1 to 5 and where Z² is a hydrogen atom or a C₁-C₅ alkyl alkyl group.

The acid labile group is a chemical moiety that undergoes a deprotection reaction in the presence of an acid. Deprotection of some acid labile groups that are used in the examples are brought on by heat. Acetal protection groups readily undergo deprotection at room temperature. The polymer of the photoresist composition undergoes a change in solubility in a developer as a result of reaction with acid generated from the photoacid generator (included in the photoresist composition) following soft bake, exposure to activating radiation and post exposure bake. This results from photoacid-induced cleavage of the acid labile group causing a change in polarity of the polymer. The acid labile group can be chosen, for example, from tertiary alkyl carbonates, tertiary alkyl esters, tertiary alkyl ethers, acetals and ketals. Preferably, the acid labile group is an ester group that contains a tertiary non-cyclic alkyl carbon or a tertiary alicyclic carbon covalently linked to a carboxyl oxygen of an ester of the polymer. The cleavage of such acid labile groups results in the formation of carboxylic acid groups.

In one embodiment, the polymer that comprises the acid-labile group includes polymerized units having the structure shown in formula (1) below:

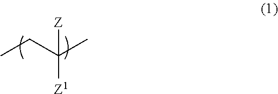

wherein Z is selected from a hydrogen atom, substituted or unsubstituted C₁-C₄ alkyl, substituted or unsubstituted C₁-C₄ fluoroalkyl or a cyano group; Z¹ is a non-hydrogen substituent comprising an acid-labile group, the cleavage of which forms a carboxylic acid on the polymer.

In an embodiment, the acid-labile group which, on decomposition, forms a carboxylic acid group on the polymer is preferably a tertiary ester group of the formula —C(O)OC(R1)3 or an acetal group of the formula —C(O)OC(R2)2OR3, wherein: R1 is each independently linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C1-6 alkyl, branched C3-6 alkyl, or monocyclic or polycyclic C3-10 cycloalkyl, each of which is substituted or unsubstituted, each R1 optionally including as part of its structure one or more groups chosen from —O—, —C(O)—, —C(O)—O—, or —S—, and any two R1 groups together optionally forming a ring; R2 is independently hydrogen, fluorine, linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably hydrogen, linear C1-6 alkyl, branched C3-6 alkyl, or monocyclic or polycyclic C3-10 cycloalkyl, each of which is substituted or unsubstituted, each R2 optionally including as part of its structure one or more groups chosen from —O—, —C(O)—, —C(O)—O—, or —S—, and the R2 groups together optionally forming a ring; and R3 is linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C1-6 alkyl, branched C3-6 alkyl, or monocyclic or polycyclic C3-10 cycloalkyl, each of which is substituted or unsubstituted, R3 optionally including as part of its structure one or more groups chosen from —O—, —C(O)—, —C(O)—O—, or —S—, and one R2 together with R3 optionally forming a ring. Such monomer is typically a vinyl aromatic, (meth)acrylate, or norbornyl monomer.

Suitable acid labile-group containing units include, for example, acid-labile (alkyl)acrylate units, such as t-butyl (meth)acrylate, 1-methylcyclopentyl (meth)acrylate, 1-ethylcyclopentyl (meth)acrylate, 1-isopropylcyclopentyl (meth)acrylate, 1-propylcyclopentyl (meth)acrylate, 1-methylcyclohexyl (meth)acrylate, 1-ethylcyclohexyl (meth)acrylate, 1-isopropylcyclohexyl (meth)acrylate, 1-propylcyclohexyl (meth)acrylate, methyladamantyl(meth)acrylate, ethyladamantyl(meth)acrylate, and the like, and other cyclic, including alicyclic, and non-cyclic (alkyl) acrylates.

Acetal and ketal acid labile groups can be substituted for the hydrogen atom at the terminal of an alkali-soluble group such as a carboxyl group so as to be bonded with an oxygen atom. When acid is generated, the acid cleaves the bond between the acetal or ketal group and the oxygen atom to which the acetal-type acid-dissociable, dissolution-inhibiting group is bonded. Exemplary such acid labile groups are described, for example, in U.S. Pat. Nos. 6,057,083, 6,136,501 and 8,206,886 and European Pat. Pub. Nos. EP01008913A1 and EP00930542A1. Also suitable are acetal and ketal groups as part of sugar derivative structures, the cleavage of which would result in the formation of hydroxyl groups, for example, those described in U.S. Patent Application No. US2012/0064456A1.

Suitable polymers include, for example, phenolic resins that contain acid-labile groups. Particularly preferred resins of this class include: (i) polymers that contain polymerized units of a vinyl phenol and an acid labile (alkyl) acrylate as described above, such as polymers described in U.S. Pat. Nos. 6,042,997 and 5,492,793; (ii) polymers that contain polymerized units of a vinyl phenol, an optionally substituted vinyl phenyl (e.g., styrene) that does not contain a hydroxy or carboxy ring substituent, and an acid labile (alkyl) acrylate such as described above, such as polymers described in U.S. Pat. No. 6,042,997; (iii) polymers that contain repeat units that comprise an acetal or ketal moiety that will react with photoacid, and optionally aromatic repeat units such as phenyl or phenolic groups; such polymers described in U.S. Pat. Nos. 5,929,176 and 6,090,526, and blends of (i) and/or (ii) and/or (iii). Such polymers are useful for imaging at wavelengths, for example, of 200 nm or greater, such as 248 nm and 365 nm.

Suitable polymers include those that are useful for imaging at certain sub-200 nm wavelengths such as 193 nm, such as those disclosed in European Patent Publication No. EP930542A1 and U.S. Pat. Nos. 6,692,888 and 6,680,159. For imaging at 193 nm wavelength, the polymers are preferably substantially free (e.g., less than 15 mole %), preferably completely free of phenyl, benzyl or other aromatic groups where such groups are highly absorbing of the radiation.

Other suitable polymers for use in the photoresist composition include, for example, those which contain polymerized units of a non-aromatic cyclic olefin (endocyclic double bond) such as an optionally substituted norbornene, for example, polymers described in U.S. Pat. Nos. 5,843,624 and 6,048,664. Still other suitable polymers for use in the photoresist composition include polymers that contain polymerized anhydride units, particularly polymerized maleic anhydride and/or itaconic anhydride units, such as disclosed in European Published Application EP01008913A1 and U.S. Pat. No. 6,048,662.

Also suitable for use in the photoresist composition is a polymer that contains repeat units that contain a hetero atom, particularly oxygen and/or sulfur (but other than an anhydride, i.e., the unit does not contain a keto ring atom). The heteroalicyclic unit can be fused to the polymer backbone and can comprise a fused carbon alicyclic unit such as provided by polymerization of a norbornene group and/or an anhydride unit such as provided by polymerization of a maleic anhydride or itaconic anhydride. Such polymers are disclosed in International Pub. No. WO0186353A1 and U.S. Pat. No. 6,306,554. Other suitable hetero-atom group containing polymers include polymers that contain polymerized carbocyclic aryl units substituted with one or more hetero-atom (e.g., oxygen or sulfur) containing groups, for example, hydroxy naphthyl groups, such as disclosed in U.S. Pat. No. 7,244,542.

The polymer may further include a unit that contains a lactone moiety for controlling the dissolution rate of the polymer and the photoresist composition. Suitable monomers for use in the polymer containing a lactone moiety include, for example, the following:

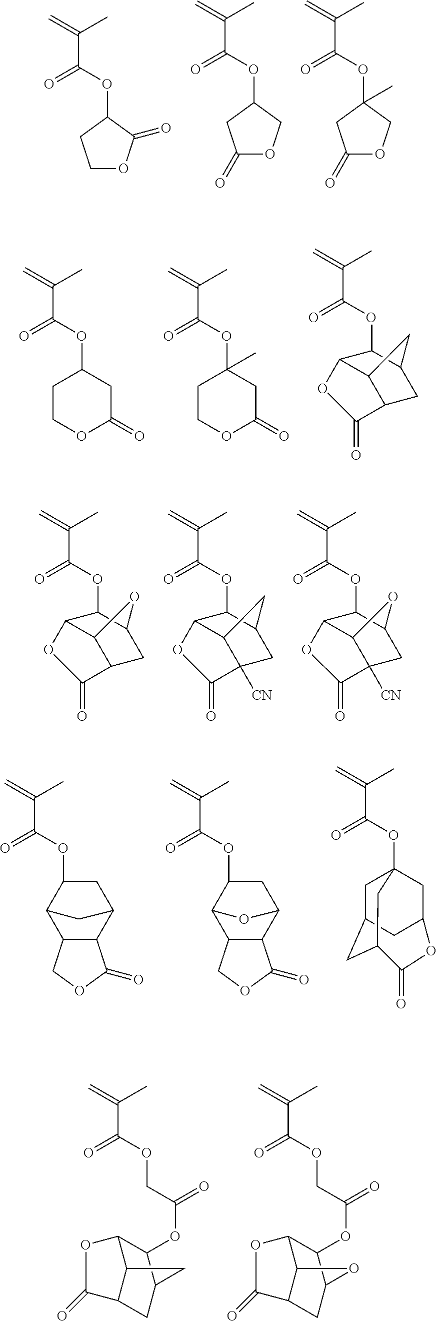

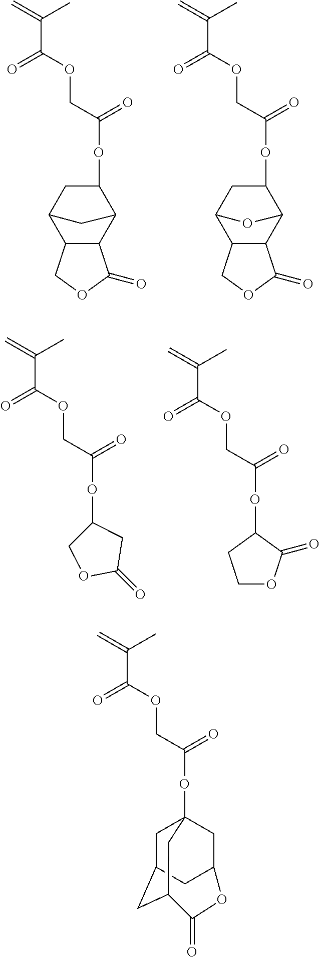

In an embodiment, the polymer further typically includes a unit containing a polar group, which enhances etch resistance of the polymer and photoresist composition and provides additional means to control the dissolution rate of the polymer and photoresist composition. Monomers for forming such a unit include, for example, the following:

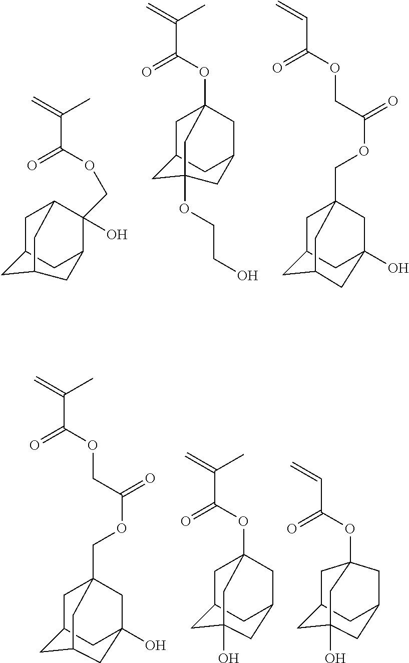

The polymer can include one or more additional units of the types described above. Typically, the additional units for the polymer will include the same or similar polymerizable group as those used for the monomers used to form the other units of the polymer, but may include other, different polymerizable groups in the same polymer backbone.

The polymer may also include one or more repeat units derived from the polymerization of a vinyl aromatic monomer. An exemplary vinyl aromatic monomer is styrene. In an embodiment, a polymer derived from a vinyl aromatic monomer has the structure shown in formula (4a) below:

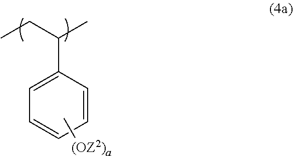

wherein a is 1 to 5 and where Z² is a hydrogen or an alkyl group having 1 to 5 carbon atoms. In a preferred embodiment, a is 1 and Z² is hydrogen. It is preferable for the vinyl aromatic monomer to have a hydroxyl group located in the para-position on the aryl ring. A preferred vinyl aromatic polymer is poly(p-hydroxystyrene) (abbreviated as PHS).

In an embodiment, the polymer for use in the photoresist composition comprises a first repeat unit of formula (3) and a second repeat unit of formula (4):

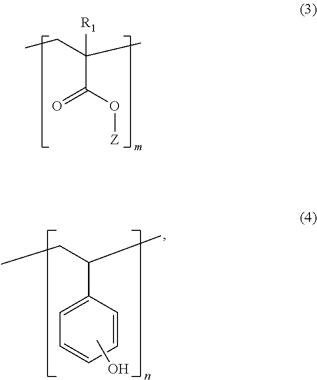

wherein R₁ is a hydrogen atom or substituted or unsubstituted C₁-C₃ alkyl; Z is a non-hydrogen substituent comprising an acid-labile moiety. In an embodiment, m+n (in formulas (3) and (4)) is 70 to 100 mole percent (mole %). In an embodiment, m is 10 to 90 mole %, preferably 15 to 50 mole %, preferably 20 to 40 mole %, and n is 10 to 80 mole %, preferably 20 to 75 mole %, and more preferably 60 to 70 mole % based on total polymerized units present in the polymer. In an embodiment, the mole ratio of n to m is 0.7 to 9, preferably 0.2 to 4.

When the polymer comprises third repeat units (that are different from the first repeat units and the second repeat units), the third repeat units may be present in the polymer in an amount of 5 to 35 mole % and preferably 10 to 30 mole %, based on total polymerized units present in the polymer.

While not to be limited thereto, exemplary polymers include, for example, the following:

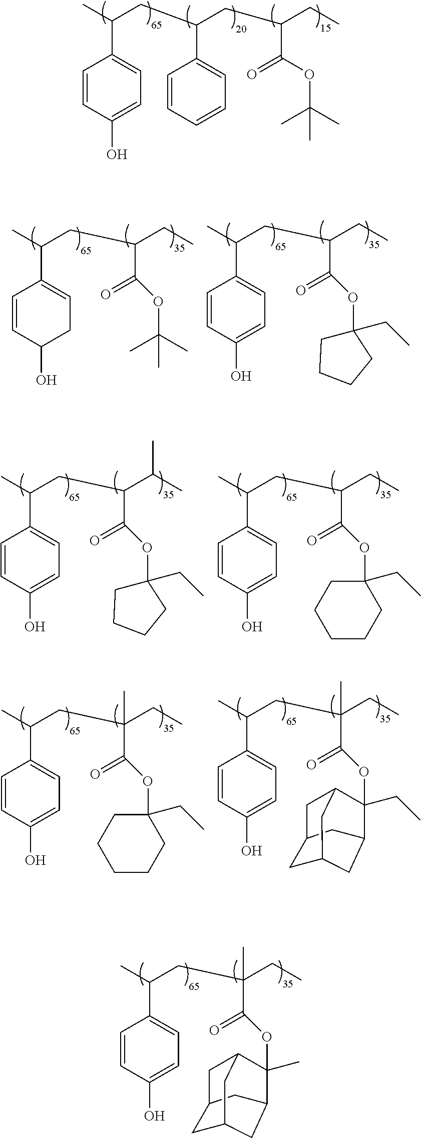

Suitable polymers for use in the photoresist compositions are commercially available and can readily be made by persons skilled in the art. The polymer is present in the photoresist composition in an amount sufficient to render an exposed coating layer of the photoresist developable in a suitable developer solution.

Typically, the polymer is present in the photoresist composition in an amount of from 70 to 100 wt % based on total solids of the photoresist composition. The weight average molecular weight Mw of the polymer is typically less than 100,000, for example, from 4000 to 100,000, more typically from 4000 to 20,000 grams per mole (g/mole) as measured by gel permeation chromatography using a polystyrene standard. Blends of two or more of the above-described polymers can suitably be used in the photoresist composition of the invention.

The photoresist composition comprises a non-ionic photoacid generator. In an embodiment, the photoresist composition may optionally contain an ionic photoacid generator. It is desirable to use photoacid generators that generate the photoacid by a Norrish-1 cleavage. The Norrish-I reaction is the photochemical cleavage or homolysis of aldehydes and ketones into two free radical intermediates. The carbonyl group accepts a photon and is excited to a photochemical singlet state. In an embodiment, the photoacid generator has the structure shown in formula (5)

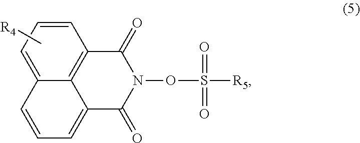

formula (4), R₄ is a hydrogen atom, a substituted or unsubstituted, linear or branched C₁ to C₁₄ alkyl group, a substituted heterocyclic group, or a halogen atom; and wherein R₅ is a substituted or unsubstituted alkyl group having 1 to 18 carbon atoms; a halogen atom, or an aryl group having 6 to 20 unsubstituted carbon atoms.

Examples of suitable photoacid generators are N-hydroxynaphthalimide trifluoromethanesulfonate (NHNI-TF), N-hydroxynaphthalimide perfluoro-1-butanesulfonate (NHNI-PFBS), N-hydroxynaphthalimide camphor-10-sulfonate, N-hydroxynaphthalimide 2-trifluoromethylphenylsulfonate, N-hydroxy-5-norbornene-2,3-dicarboximide perfluoro-1-butanesulfonate, N-(trifluoromethylsulfonyloxy)phthalimide, N-hydroxysuccinimide perfluorobutanesulfonate or benzeneacetonitrile, 2-methyl-α-[2-[[(propylsulfonyl)oxy]imino]-3(2H)-thienylidene]—(commercially available as IRGACURE PAG 103). In a preferred embodiment, the photoacid generator may be one or more of the structures of formulas (5a) or (5b) shown below

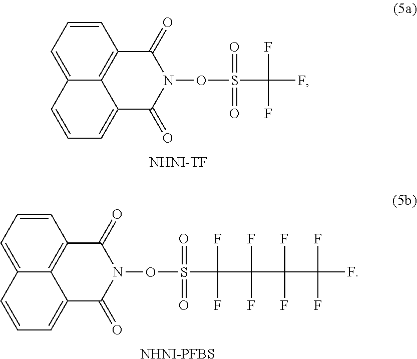

The photoacid generator is present in the photoresist composition in an amount of from 0.2 to 15 wt %, more typically 0.3 to 5 wt %, and more preferably 0.5 to 3 wt %, based on total solids of the photoresist composition. By minimizing photoacid generator loading, UV transparency of the photoresist also can be minimized. It increases UV transparency of photoresist layer.

As noted above, the photoresist composition contains a non-ionic thioxanthone compound and/or a non-ionic oxime compound to improve the process window, and to prevent void formation during dry plasma etching. The non-ionic thioxanthone compound may be used in the photoresist composition either singly or in conjunction with the non-ionic oxime compound. The non-ionic thioxanthone compound has the structure of formula (6)

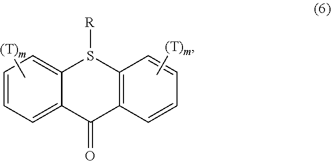

where R is a non-hydrogen substituent; each T is independently a hydrogen atom, a substituted or unsubstituted C₁₋₅ alkyl, amino, mercapto or hydroxyl; and each m is independently an integer from 0 to 4. In an embodiment, each T is independently a hydrogen atom or a substituted or unsubstituted C₁₋₃ alkyl group. In another embodiment, the non-ionic thioxanthone compound is 2-isopropylthioxanthenone, diethylthioxanthone, or a combination thereof.

The non-ionic thioxanthone compound may be used in the photoresist composition in an amount of 0.05 to 3 wt %, preferably 0.08 to 2 wt %, and more preferably 0.1 to 1.5 wt %, based on a total solids of the photoresist composition.

In an embodiment, the non-ionic oxime compound has the formula (7A)

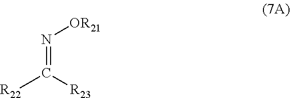

where in formula (7A), R₂₁ is a hydrogen atom, substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, substituted or unsubstituted C₄₋₂₀ heteroarylalkyl, or a combination thereof, R₂₁ optionally including a —C(O)— group bonded to the O atom; R₂₂ an R₂₃ are each independently a hydrogen atom, substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, substituted or unsubstituted C₄₋₂₀ heteroarylalkyl; or a combination thereof; provided R₂₂ and R₂₃ cannot both be a hydrogen atom; and R₂₂ and R₂₃ are optionally connected to each other via a single bond or a divalent linking group to form a ring. The rings formed by the fusion of R₂₂ and R₂₃ may include one of the following structures.

In an embodiment, R21 comprises a —C(O)— group bonded to the O atom and R22 and R23 are connected to each other via a single bond or a divalent linking group to form a ring.

In an embodiment, the R22 and R23 may be used to form fluorene.

In an embodiment, preferred non-ionic oximes include 1-(2-naphthalenyl)ethanone O-(2-phenylacetyl)oxime (also sometimes referred to as (E)-1-(naphthalen-2-yl)ethan-1-one O-(2-phenylacetyl) oxime (hereinafter Oxime A)) and (9H-fluoren-9-one, O-(2-phenylacetyl)oxime) (also sometimes referred to as 9H-fluoren-9-one O-(2-phenylacetyl) oxime) (hereinafter Oxime B).

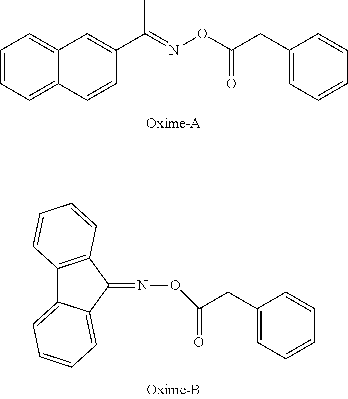 [SMILES: C/C(=N\OC(=O)Cc1ccccc1)c1ccc2ccccc2c1 ; O=C(Cc1ccccc1)ON=C1c2ccccc2-c2ccccc21]

The non-ionic oxime compound may be used in the photoresist composition in an amount of 0.1 to 1.5 wt %, preferably 0.2 to 1 wt %, based on a total solids content of the photoresist composition.

The photoresist composition also comprises a base quencher. The base quencher enhances the resolution of the developed resist relief image. However, nonionic photoacid generator that listed as an embodiment, decomposes in the presence of basic substance. Thus, the lower basicity is favorable to prevent decomposition of the photoacid generator during the storage of the photoresist composition.

The base quencher is selected from N-diethyldodecanamide, 2,8-dimethyl-6H,12H-5,11-methanodibenzo[b,f][1,5]diazocine (Troger's Base), 1,1-dimethylethyl 4-hydroxypiperidine-1-carboxylate, N-allylcaprolactam, ethyl-3-(morpholino)propionate, 4-(p-tolyl)morpholine, or a combination thereof. A preferred base quencher is 2,8-dimethyl-6H,12H-5,11-methanodibenzo[b,f][1,5]diazocine (Troger's Base).

The amount of the base quencher in the photoresist layer is preferably from 0.001 to 1.0 wt %, more preferably from 0.01 to 0.8 wt % or from 0.02 to 0.2 wt % based on the total weight of solids in the photoresist composition.

### Solvent

The photoresist composition further comprises a solvent. The solvent is used to solvate the polymer and to facilitate miscibility of the various ingredients used in the composition.

Solvents generally suitable for dissolving, dispensing, and coating include anisole, alcohols including 1-methoxy-2-propanol (also referred to as propylene glycol methyl ether, PGME), and 1-ethoxy-2 propanol, esters including n-butyl acetate, 1-methoxy-2-propyl acetate (also referred to as propylene glycol methyl ether acetate, PGMEA), methoxyethyl propionate, ethoxyethyl propionate, ketones including cyclohexanone, 2,6-dimethyl-4-heptanone, 2 heptanone; ethyl lactate (EL), 2-hydroxyisobutyric acid methyl ester (HBM), gamma-butyrolactone (GBL), 3-methoxypropanoic acid methyl ester, and combinations thereof.

The solvent amount can be, for example, 20 to 98 wt %, preferably 40 to 90 wt %, and more preferably 60 to 80 wt %, based on the total weight of the photoresist composition. It will be understood that “polymer” used in this context of a component in the photoresist layer may mean only the polymers (that contain the acid labile group) disclosed herein. It will be understood that total solids include the polymer, base quencher, surfactant (if used), photoacid generator, and any optional additives, exclusive of solvent. The solids content of the composition may be 2 to 80 wt %, preferably 10 to 60 wt %, based on the total weight of the photoresist composition.

The photoresist composition can comprise other optional ingredients, such as one or more surface leveling agent (SLA), adhesion promoter and/or plasticizer. If used, the SLA is preferably present in an amount of from 0.001 to 0.1 wt %, based on total weight of solids of the photoresist composition, and if used, the adhesion promoter and/or plasticizer each are present in an amount of from 0.1 to 10 wt %, based on total weight of solids of the photoresist composition.

The photoresist composition further comprises weak acidic or basic compounds that facilitate controlling the influence of the substrate. A footing profile is typically produced in the photoresist when it is disposed on metal substrates such as copper. These weak acidic or basic compounds form a passivation layer on the metal surface, which reduce its influence. If used, the weak acidic or basic compounds are present in an amount of 0.001 to 0.1 wt %, based on weight of solid of photoresist composition.

The photoresist composition is applied to the first layer 102 to form the photoresist layer 106. In an embodiment, the photoresist layer has a thickness of greater than 2 micrometers. The photoresist composition is generally applied upon a surface of the metal layer via spin-coating, dipping, roller-coating or some other conventional coating technique. Spin-coating is preferred. For spin-coating, the solids content of the coating solution can be adjusted to provide a desired film thickness based upon the specific coating equipment utilized, the viscosity of the solution, the speed of the coating tool and the amount of time allowed for spinning. In an embodiment, the photoresist composition is applied in a single application.

The photoresist composition layer is then patternwise exposed to activating radiation through a photomask to create a difference in solubility between exposed and unexposed regions. With reference to the FIG. 1B, after the deposition of the photoresist layer 106, a mask 110 is disposed on the photoresist layer 106 in order to photo-pattern the photoresist layer 106. A UV light having a wavelength of 10 to 500 nanometers may be used in the photopatterning. The exposed portions of the photoresist layer may be removed by aqueous alkaline developer, such as 2.38 wt % tetra methyl ammonium hydride followed by water rinse and spin dry as seen in the FIG. 1C.

References herein to exposing a photoresist composition layer to radiation that is activating for the layer indicates that the radiation is capable of forming a latent image in the layer. The photomask has optically transparent and optically opaque regions corresponding to regions of the resist layer to be exposed and unexposed, respectively, by the activating radiation. The exposure wavelength is typically sub-500 nm, such as from 200 to 500 nm of UV-visible light. Preferably, the exposure is conducted with radiation of 365 nm wavelength from a mercury lamp (i-line).

Following exposure of the photoresist composition layer, a post exposure bake (PEB) is typically performed to decompose the acid labile group by acid that generated from the PAG during the exposure step. The PEB can be conducted, for example, on a hotplate or in an oven. A latent image defined by the boundary between polarity-switched and unswitched regions (corresponding to exposed and unexposed regions, respectively) is thereby formed.

The photoresist composition layer is next contacted with an alkaline developing solution to remove exposed portions of the layer, leaving unexposed regions forming a resist pattern. The developer is typically an aqueous alkaline developer, for example, a quaternary ammonium hydroxide solution, for example, a tetra-alkyl ammonium hydroxide solutions such as 0.26 Normality (N) (2.38 wt %) tetramethylammonium hydroxide (TMAH).

A further aspect is a process for dry plasma etching of the first layer 102. The first 102 is partially removed by using photoresist relief pattern as etching mask. After dry plasma etching, any remaining portions of the photoresist composition can be removed (stripped) from the substrate.

This invention is advantageous in that the photoresist composition may be used to obtain wider process window on lithographic process to form an etching mask. Then the etching mask formed by the photoresist gives stronger resistance against etching process by reducing formation of voids that is caused by outgassing from an acid labile group of polymers.

The invention will now be exemplified by the following non-limiting examples.

### EXAMPLES

### Example 1

This example was conducted to determine the process window for photoresist compositions that did not contain either a non-ionic thioxanthone compound or a non-ionic oxime compound, contained either a non-ionic thioxanthone compound or a non-ionic oxime compound, or contained both a non-ionic thioxanthone compound and a non-ionic oxime compound. The compositions contained one of an Additive-A and Additive-B to control pattern profile. Either additive facilitates a removal of the footing profile.

For this example, the photoacid generator (PAG-1) is N-hydroxynaphthalimide trifluoromethanesulfonate. The base quencher (Base-A) is Troger's base. Additive-A is 1H-1,2,3-benzotriazole. Additive-A has weaker basicity than the base quencher. Additive-B is trithiocyanuric acid. 2-isopropylthioxanthenone (ITX) and diethylthioxanthone (DETX) are the non-ionic thioxanthone compounds that reduce photoacid generation by the photoacid generator. The non-ionic oxime compounds (e.g., the additives that produce the base quencher that improve the processing window) that improve the processing window include 1-(2-naphthalenyl)ethanone O-(2-phenylacetyl)oxime (also called Oxime-A)) and (9H-fluoren-9-one, O-(2-phenylacetyl)oxime) (also called Oxime-B). The structures of all of the aforementioned materials are shown below.

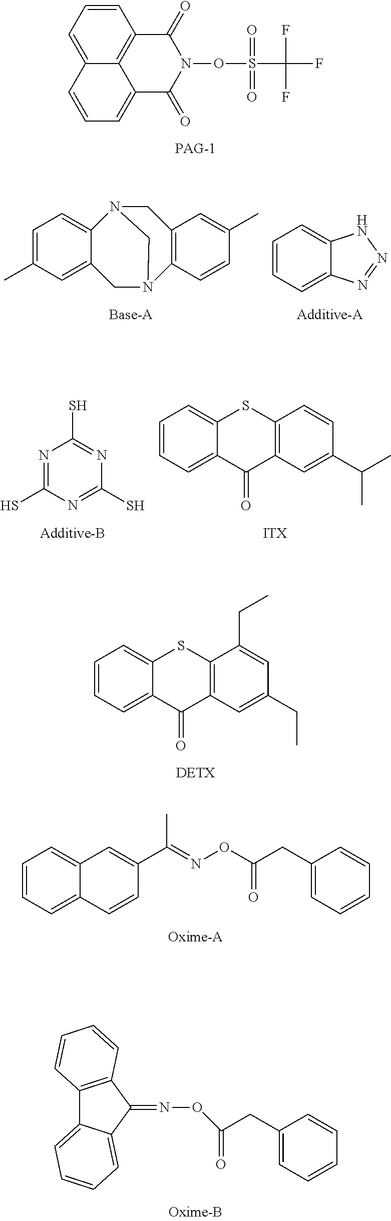

All sample contains 0.02 wt % of POLYFOX PF-656, which is a by weight of PGMEA/GBL is 98/2.

The acid labile polymer of the photoresist composition has a weight average molecular weight (Mw) of 23,000 grams per mole and comprises 35 mole percent of tertiary butyl alcohol and 65 mole percent of polyhydroxystyrene. Table 1 shows samples of the photoresist composition with the solids content shown as parts by weight (pbw).

The comparative photoresist compositions shown in Table 1 are CF-5 through CF-8. The comparative compositions do not contain an oxime or a thioxanthone. The exemplary compositions EX-1 through EX-21 contains one of the non-ionic oxime compounds or the non-ionic thioxanthone compounds or both the non-ionic oxime compound and the non-ionic thioxanthone compound.

A 150 nm thick titanium layer was deposited on 150 mm silicon substrates. A 200 nm thick copper layer was then deposited on the titanium layer by sputtering. The surface of the copper layer was washed using a solution of 10 wt % sulfuric acid (H2SO4) for 30 seconds to remove the surface oxidation layer, followed by a deionized (DI) water rinse. The water was then removed by blowing a stream of pressurized nitrogen onto the substrate. The substrate was puddle wetted with a 2.38 wt % TMAH solution for 60 seconds, followed by a deionized water rinse. The substrate was then spin-dried. No primer was used on the copper layer.

The photoresist composition was then spin coated on the substrate using a D-Spin 60A SK-W60A-AVP wafer track (Sokudo). The spin speed was adjusted to obtain a 7.5 micrometer (μm) thick photoresist layer after a 135° C. soft-bake for 90 seconds.

The photoresist layer was then subjected to mask exposure by a NSR-2005i9C (Nikon) light source using a numerical aperture of 0.50 NA. A post exposure bake (PEB) and develop process was applied by a Clean Track Mk-Vz (Tokyo Electron). PEB process was applied at 110° C. was conducted for 90 seconds. Then, the photoresist layer is puddle developed in a 2.38 wt % TMAH aqueous developer (MF™ CD-26, DuPont Electronics & Industrial) for 80 seconds. Following the developing, the substrate was then rinsed with water and spin-dried. The term “puddle development” typically refers to a specific development technique used in photoresist processing. Puddle development involves allowing the developer solution to pool or form a “puddle” on the surface of the photoresist during the development step.

The stability of pattern width against variations in focus position and energy strength during the mask exposure step of the lithography process (Focus-Exposure Matrix=FEM) was assessed using a 1.2 μm trench mask. The objective is to evaluate a pattern width that is 100 nm narrower than the nominal size, focusing on the under-dose process window. The process window was quantified as the focus latitude that provides a 5% exposure margin corresponding to a variation of plus or minus 10% from the target pattern size (1210 nm to 990 nm). Calculations were performed using ProData software by KLA-TENCOR.

Table 2 presents the results of lithographic testing and process window evaluations. To assess the impact of analogues of both non-ionic oxime and non-ionic thioxanthone compounds, their loading amounts are depicted as relative values against the molar amount of the PAG, as shown in Table 2.

TABLE 1

| | | | | Base | | Oxime | | | |
|---|---|---|---|---|---|---|---|---|---|
| ID | Polymer | PAG | Base | Loading | Additive | Compound | Loading | Thioxanthone | Loading |
| CF-5 | A | PAG-1 | Base-A | 0.158% | Additive-A | NONE | | NONE | 0.0% |
| EX-1 | | 1.3 wt % | | 0.158% | | NONE | 0 | ITX | 0.10% |
| EX-2 | | | | 0.158% | | NONE | 0 | ITX | 0.48% |
| EX-3 | | | | 0.158% | | NONE | 0 | ITX | 0.96% |
| CF-6 | | | | 0.144% | Additive-B | NONE | 0 | NONE | 0.0% |
| CF-7 | | | | 0.158% | | NONE | 0 | NONE | 0.0% |
| CF-8 | | | | 0.205% | | NONE | 0 | NONE | 0.0% |
| EX-4 | | | | 0.158% | | NONE | 0 | ITX | 0.10% |
| EX-5 | | | | 0.158% | | NONE | 0 | ITX | 0.48% |
| EX-6 | | | | 0.158% | | NONE | 0 | ITX | 0.96% |
| EX-7 | | | | 0.158% | | NONE | 0 | DETX | 0.10% |
| EX-8 | | | | 0.158% | | NONE | 0 | DETX | 0.48% |
| EX-9 | | | | 0.158% | | NONE | 0 | DETX | 0.10% |
| EX-10 | | | | 0.158% | | Oxime-A | 0.230% | NONE | 0.0% |
| EX-11 | | | | 0.158% | | OXIME-A | 0.115% | ITX | 0.48% |
| EX-12 | | | | 0.158% | | OXIME-A | 0.230% | ITX | 0.48% |
| EX-13 | | | | 0.158% | | OXIME-B | 0.118% | ITX | 0.48% |
| EX-14 | | | | 0.158% | | OXIME-B | 0.236% | ITX | 0.48% |
| EX-15 | | | | 0.158% | | OXIME-A | 0.230% | ITX | 0.29% |
| EX-16 | | | | 0.158% | | OXIME-A | 0.230% | DETX | 0.48% |
| EX-17 | | | | 0.158% | | OXIME-A | 0.230% | ITX | 0.67% |
| EX-18 | | | | 0.158% | | OXIME-A | 0.459% | ITX | 0.29% |
| EX-19 | | | | 0.158% | | OXIME-A | 0.459% | ITX | 0.48% |
| EX-20 | | | | 0.158% | | OXIME-A | 0.459% | ITX | 0.67% |
| EX-21 | | | | 0.158% | | OXIME-A | 0.459% | NONE | 0.0% |

TABLE 2

| | | | | Oxime | | Thioxanthone | | Energy to | PW 1100 nm |
|---|---|---|---|---|---|---|---|---|---|
| | Base | | Oxime | compounds/ | | IPAG | UFTL | 1100 nm | CD target, 5% |
| | Loading | Additives | Compound | PAG mol % | Thioxanthone | mol % | [nm] | [msec] | EL [μm] |
| CF-5 | 0.158% | Additive-A | NONE | 0% | NONE | 0% | 245 | 210 | 0.35 |
| Ex-1 | | | NONE | 0% | ITX | 10% | 215 | 218 | 0.43 |
| Ex-2 | | | NONE | 0% | ITX | 50% | 169 | 234 | 1.03 |
| Ex-3 | | | NONE | 0% | ITX | 100% | 125 | 243 | 1.59 |
| CF-6 | 0.144% | Additive-B | NONE | 0% | NONE | 0% | 247 | 175 | 0.43 |
| CF-7 | 0.158% | | NONE | 0% | NONE | 0% | 248 | 187 | 0.49 |
| CF-8 | 0.205% | | NONE | 0% | NONE | 0% | 257 | 273 | 0.89 |
| EX-4 | 0.158% | | NONE | 0% | ITX | 10% | 222 | 195 | 0.55 |
| EX-5 | 0.158% | | NONE | 0% | ITX | 50% | 169 | 200 | 0.96 |
| EX-6 | 0.158% | | NONE | 0% | ITX | 100% | 130 | 203 | 1.35 |
| EX-7 | 0.158% | | NONE | 0% | DETX | 10% | 234 | 194 | 0.52 |
| EX-8 | 0.158% | | NONE | 0% | DETX | 50% | 179 | 198 | 0.93 |
| EX-9 | 0.158% | | NONE | 0% | DETX | 100% | 140 | 200 | 1.05 |
| EX-10 | 0.158% | | OXIME-A | 20% | NONE | 0% | 218 | 224 | 1.15 |
| EX-11 | 0.158% | | OXIME-A | 10% | ITX | 50% | 169 | 223 | 1.40 |
| EX-12 | 0.158% | | OXIME-A | 20% | ITX | 50% | 168 | 244 | 1.60 |
| EX-13 | 0.158% | | OXIME-B | 10% | ITX | 50% | 168 | 226 | 1.59 |
| EX-14 | 0.158% | | OXIME-B | 20% | ITX | 50% | 164 | 227 | 1.60 |
| EX-15 | 0.158% | | OXIME-A | 20% | ITX | 30% | 186 | 233 | 1.20 |
| EX-16 | 0.158% | | OXIME-A | 20% | DETX | 50% | 175 | 243 | 1.59 |
| EX-17 | 0.158% | | OXIME-A | 20% | ITX | 70% | 144 | 252 | 1.60 |
| EX-18 | 0.158% | | OXIME-A | 40% | ITX | 30% | 160 | 262 | 1.60 |
| EX-19 | 0.158% | | OXIME-A | 40% | ITX | 50% | 145 | 273 | 1.59 |
| EX-20 | 0.158% | | OXIME-A | 40% | ITX | 70% | 130 | 276 | 1.60 |

### Effect of Thioxanthone Addition to the Photoresist Compositions

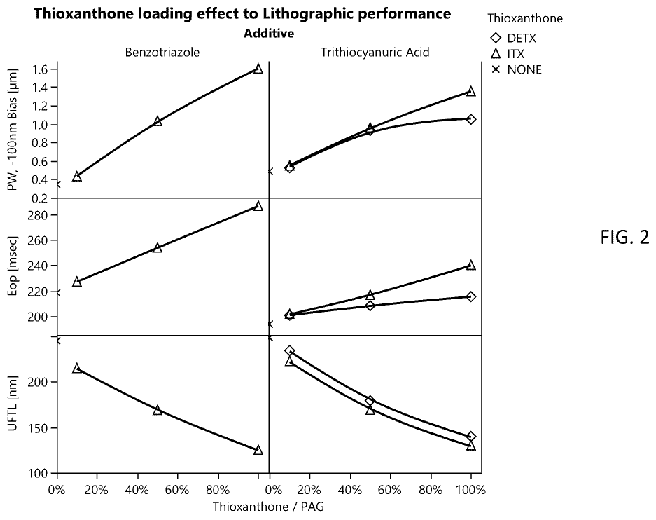

The impact of the thioxanthone additive in the photoresist compositions was assessed a) by using it individually in the form of a single additive (ITX) in a quantity suitable for mitigating footing on a copper substrate; or b) by dividing the total quantity used in (a) and adding it in the form of two distinct additives (ITX and DETX). FIG. 2 graphically depicts the non-ionic thioxanthone loading effect on unexposed area film thickness loss (UFTL) (bottom graphs), energy to −100 nm bias to nominal mask size (middle graphs) and process window at −100 nm mask bias from 1200 nm nominal (top graphs). The utilization of the non-ionic thioxanthone compound resulted in a reduction in unexposed area film thickness loss (UFTL) and a decrease in sensitivity, as illustrated in FIG. 2. This trend persisted when comparing different types of thioxanthone (ITX and DETX) or different additives (benzotriazole and trithiocyanuric acid). Notably, benzotriazole, acting as a weak base in iCAR, exhibited slower sensitivity (Eop, energy to nominal mask size, 1200 nm).

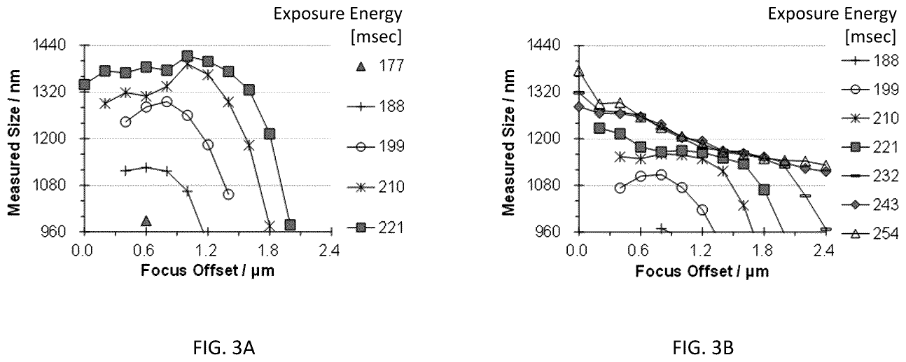

FIGS. 3A and 3B depicts pattern space width variation against focus position and exposure energy, as represented by a Bossung Curve. FIG. 3A depicts the Bossung curve of the photoresist composition without ITX (photoresist composition CF-7 from Table 1) while FIG. 3B depicts the curve for a photoresist composition with ITX (photoresist composition EX-5 from Table 1). The exposure tool uses “msec” as unit of exposure energy. It is time to exposure, and nearly equal to ½ mJ/cm². A Bossung curve, also known as the focus-exposure matrix or process window, is a graphical representation used in lithography to analyze the performance of a photolithographic process. It illustrates how the critical dimension (CD) of a pattern (such as the width of a line) varies with changes in both the focus position and exposure energy during the lithographic exposure step. The x-axis of the Bossung curve typically represents the focus position, indicating the position of the photoresist layer in the vertical direction relative to the focal plane of the imaging system. The y-axis represents the exposure energy, which is the amount of light or other radiation used during the exposure. The Bossung curve helps determine the optimal conditions for producing patterns with the desired dimensions. The addition of ITX (FIG. 3B based on EX-5) resulted in a narrower pattern width variation against both exposure energy and focus position variations compared to the composition that did not contain ITX (FIG. 3A based on CF-7). In other words, the pattern width tends to stabilize (for the photoresist composition (EX-5) containing ITX) with an increase in exposure energy when compared with an equivalent comparative composition (CF-7) that while containing the same ingredients, did not contain the ITX.

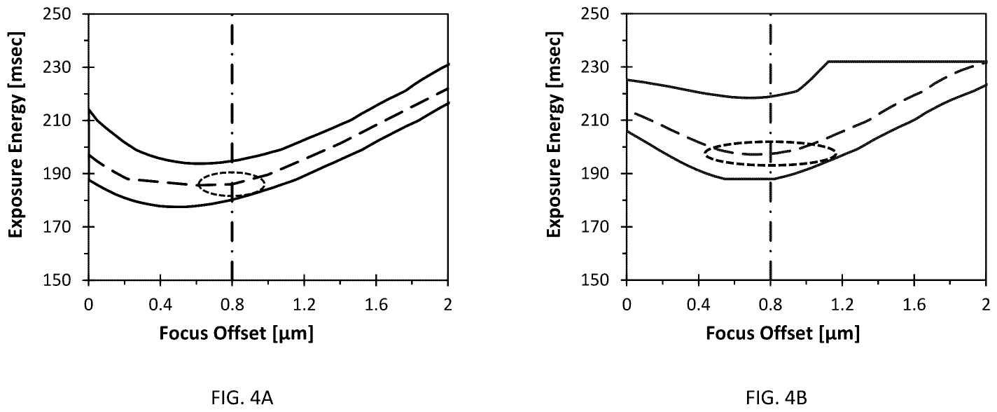

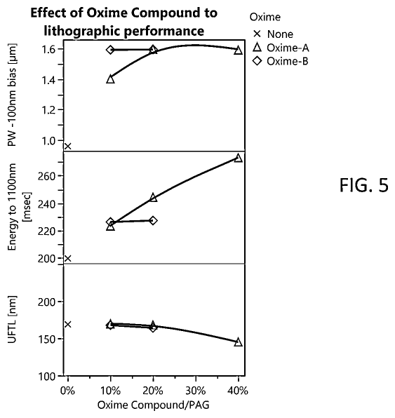

FIGS. 4A and 4B illustrate examples of a process window plot, using a nominal mask size of 1200 nm. FIG. 4A illustrates the focus exposure matrix process window (PW) for comparative example CF-7 (which does not contain ITX) aimed at achieving a 1.1 μm space width, utilizing a 1.2 μm nominal mask. FIG. 4B illustrates the focus exposure matrix process window (PW) for example EX-5 (which contains ITX) aimed at achieving the same space width, utilizing the same nominal mask. The process window is designed with a 5% exposure margin, allowing for plus or minus 10% pattern size variation against the target size. As see previously in the FIG. 3B, the pattern width tended to stabilize (for the photoresist composition (EX-5) containing ITX) with an increase in exposure energy when compared with an equivalent comparative composition (CF-7) that while containing the same ingredients, does not contain the ITX. In this evaluation, the process window was determined at a lower exposure energy, resulting in a −100 nm bias (1100 nm) from the nominal mask size (1200 nm). A pattern width allowance of plus or minus 10% against the target size is considered, and the exposure latitude is calculated at each focus offset. It is defined as the ratio of the differences between the exposure energy for plus 10% pattern size (E+10%, 1210 nm=1100 nm×110%) and minus 10% (E-10%, 990 nm) to the energy for the target size (E-100 nm bias, 1100 nm).

$$EL = \frac{[ ( E + 10 \% ) - ( E - 10 \% ) ]}{E - 100 nm bias}$$

The focus range providing a 5% EL margin is employed as the process window in this evaluation. Surprisingly, the addition of the non-ionic thioxanthone compound tends to result in a wider process window. For instance, CF7 and EX5 have the same formulation except for the non-ionic thioxanthone compound. As indicated in the plots, the addition of ITX results in a more stable critical dimension (CD) variation against both exposure energy and focus position (offset). EX5 yields a process window of 0.96 μm (See elliptical region in FIG. 4B.) by maintaining plus or minus 10% of pattern width variation compared to the undersize. This represents nearly a two-fold improvement in process window compared to the baseline, CF7 (0.49 μm) (See elliptical region in FIG. 4A.).

### Effect of Oxime Addition to the Photoresist Composition

The lithographic performance of non-ionic oxime additives ethanone (1-(2-naphthalenyl)-, O-(2-phenylacetyl)oxime) (Oxime-A)) and (9H-fluoren-9-one, O-(2-phenylacetyl)oxime) (Oxime-B) were evaluated in the photoresist composition. The test results from Table 2 shows addition of non-ionic oxime compounds increases process window with and without non-ionic thioxanthone compound.

FIG. 5 depicts a series of graph that depicts the influence of oxime compounds on the unexposed area film thickness loss (UFTL) (bottom plot), sensitivity (energy to −100 m bias, middle plot), and process window (PW 100 nm bias, top plot) for photoresist compositions that contain oxime additives. FIG. 5 depicts data for EX-5, EX-11, EX-12, EX-14 and EX-19 from Table 2.

FIG. 5 shows that photoresist compositions that contain an increased amount of a non-ionic oxime compound (such as Oxime A) demonstrate a reduced amount of UFTL. This trend is similar to that observed when incorporating non-ionic thioxanthone compounds into the photoresist compositions (See FIG. 2.). Moreover, the process window was further expanded by introducing non-ionic oxime compounds beyond the baseline formulation that already included non-ionic thioxanthone compounds.

### Example 2

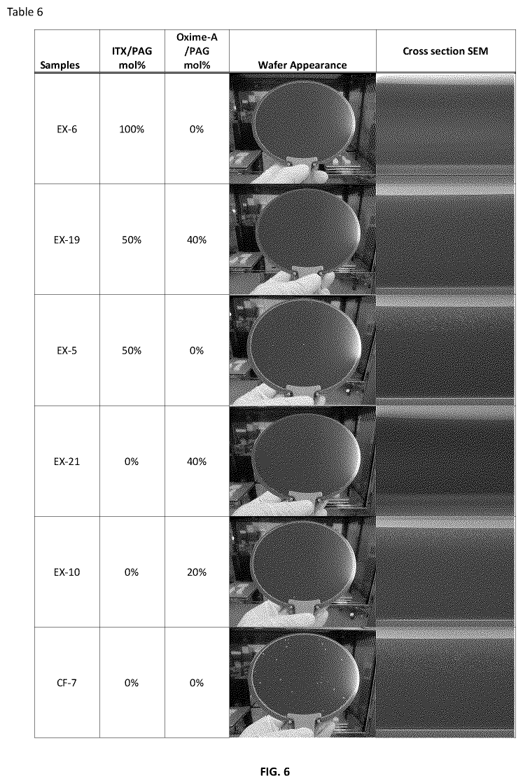

The impact of non-ionic thioxanthone and non-ionic oxime compounds on dry etching resistance was assessed. Process conditions and plasma etching conditions are detailed in Tables 4 and 5 respectively. Table 6 (shown in FIG. 6) presents the wafer appearance and corresponding cross-section SEM images post-plasma etching.

From Table 6, it may be seen that sample CF-7 (See Table 1) which is devoid of both thioxanthone (ITX) and oxime compound (Oxime A), exhibits blisters on its surface. The addition of either ITX or Oxime-A results in a reduction in the number and size of these blisters, signifying improvement. Upon scanning electron microscopy (SEM) inspection of the cross-section, tiny and circular voids were observed, with their size decreasing closer to the photoresist surface. The introduction of ITX or Oxime-A further diminished the size and thickness of the void distribution from the surface.

TABLE 4

| | |
|---|---|
| Substrate | Silicon |
| Primer | HMDS (hexamethyldisilizane) |
| Pre-Bake | 135° C./90 seconds |
| Film thickness | 10 μm |
| Exposure | i-line, NSR-2005i9C, 0.50NA/0.68PC |
| P.E.B | 110° C./90 sec |
| Developer | MF ™ CD-26, 2.38 wt % TMAH, 80 sec Single puddle |

TABLE 5

| | |
|---|---|
| Tool | SAMCO, RIE-10NR |
| Gas Flow | SF₆/O₂ = 66/10 SCCM |
| RF Power | 250 W |
| Etching time | 150 sec |

Without being limited to theory, the observed blisters (in comparative sample CF-7) are likely an aggregation of tiny voids produced by outgassing from the acid-labile polymer in the photoresist. During plasma etching, UV emission may play a significant role in the generation of photoacid from the photoacid generator (PAG). This photoacid is believed to decompose the acid-labile groups, acting as a source of outgassing.

As demonstrated above, both the non-ionic thioxanthone (ITX) and oxime compounds (Oxime-A) contribute to a wider process window, particularly in the under-dose

1. A photoresist composition, comprising:
a non-ionic thioxanthone compound, a non-ionic oxime compound, or a combination of a non-ionic thioxanthone compound and a non-ionic oxime compound;
a polymer comprising a first repeat unit of formula (3) and a second repeat unit of formula (4a): 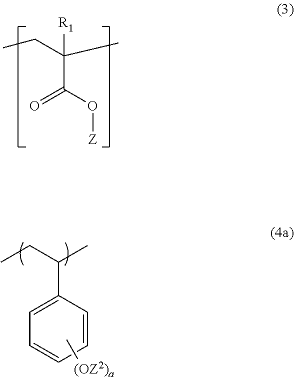
wherein in formula (3), R₁ is a hydrogen atom or a substituted or unsubstituted C₁ to C₃ alkyl group; Z is a non-hydrogen substituent comprising an acid-labile moiety; and wherein in formula (4a), a is an integer from 1 to 5 and where Z² is a hydrogen atom or a substituted or unsubstituted C₁ to C₅ alkyl group;
a base quencher;
a photoacid generator; and
a solvent.

2. The photoresist composition of claim 1, where the non-ionic thioxanthone compound has the structure of formula (6) 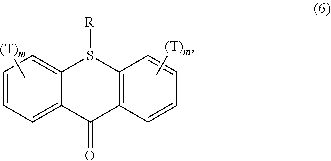
where R is a non-hydrogen substituent; each T is independently a hydrogen atom, a substituted or unsubstituted C₁₋₅ alkyl, amino, mercapto or hydroxyl; and each m is independently an integer from 0 to 4.

3. The photoresist composition of claim 2, where each T is independently a hydrogen atom or a substituted or unsubstituted C₁₋₃ alkyl group.

4. The photoresist composition of claim 1, where the non-ionic thioxanthone compound is 2-isopropylthioxanthone, diethylthioxanthone, or a combination thereof.

5. The photoresist composition of claim 1, where the non-ionic oxime compound has the formula (7A) 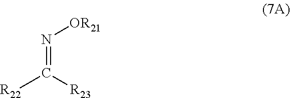
where in formula (7A), R₂₁ is a hydrogen atom, substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, substituted or unsubstituted C₄₋₂₀ heteroarylalkyl, or a combination thereof, R₂₁ optionally including a —C(O)— group bonded to the O atom; R₂₂ an R₂₃ are each independently a hydrogen atom, substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, substituted or unsubstituted C₄₋₂₀ heteroarylalkyl; or a combination thereof, provided R₂₂ and R₂₃ cannot both be a hydrogen atom; and R₂₂ and R₂₃ are optionally connected to each other via a single bond or a divalent linking group to form a ring.

6. The photoresist composition of claim 5, where R₂₁ comprises a —C(O)— group bonded to the O atom.

7. The photoresist composition of claim 6, where R₂₂ and R₂₃ are connected to each other via a single bond or a divalent linking group to form a ring.

8. The photoresist composition of claim 1, wherein the photoacid generator is selected from N-hydroxynaphthalimide trifluoromethanesulfonate, N-hydroxynaphthalimide perfluoro-1-butanesulfonate, N-hydroxynaphthalimide camphor-10-sulfonate, N-hydroxynaphthalimide 2-trifluoromethylphenylsulfonate, N-hydroxy-5-norbornene-2,3-dicarboximide perfluoro-1-butanesulfonate, N-(trifluoromethylsulfonyloxy)phthalimide and N-hydroxysuccinimide perfluorobutanesulfonate.

9. The photoresist composition of claim 1, wherein the base quencher is selected from N-diethyldodecanamide, 2,8-dimethyl-6H,12H-5,11-methanodibenzo[b,f][1,5]diazocine (Troger's Base), 1,1-dimethylethyl 4-hydroxypiperidine-1-carboxylate, N-allylcaprolactam, ethyl-3-(morpholino)propionate, 4-(p-tolyl)morpholine, or a combination thereof.

10. A patterning method, comprising:
providing a substrate;
forming a photoresist layer on the substrate, wherein the photoresist layer is formed from a photoresist composition of claim 1;
patternwise exposing the photoresist layer to activating radiation; and
contacting the photoresist layer with a developing solution, thereby forming a photoresist pattern.
